(19) United States
(12) Patent Application Publication
(10) Pub. No.: US 2026/0247552 A1
(43) Pub. Date: Aug. 20, 2026

(54) DRIP-PROOF SHEET AND ELECTRONIC CONTROL UNIT

(71) Applicant: DENSO CORPORATION, Kariya-city (JP)

(72) Inventor: Go SATO, Kariya-city (JP)

(21) Appl. No.: 19/452,614

(22) Filed: Jan. 19, 2026

(30) Foreign Application Priority Data
Feb. 17, 2025 (JP) 2025-023759

(51) Int. Cl. H05K 5/03; H01R 13/52; H05K 5/02; H05K 5/06; H05K 7/20

(52) U.S. Cl. CPC H05K 5/03; H01R 13/5213; H01R 13/5216; H05K 5/0247; H05K 5/069; H05K 7/20418

(57) ABSTRACT

A drip-proof sheet is attached to an electronic control device that includes a circuit board and a housing. The circuit board includes a wiring board on which a connector is mounted. The housing accommodates the circuit board with the connector exposed to an outside. The drip-proof sheet includes a fixation section, a drip-proof section, and a positioning section. The fixation section is secured to the electronic control device. The drip-proof section protrudes beyond a connector wall portion of the housing to reduce water ingress to the connector. The connector wall portion is a wall from which the connector is exposed to the outside. The positioning section is attached to the electronic control device by engagement that causes the fixation section and the drip-proof section to be positioned such that the fixation section is secured to the electronic control device and the drip-proof section protrudes beyond the connector wall portion.

### CROSS REFERENCE TO RELATED APPLICATION

The present application claims the benefit of priority from Japanese Patent Application No. 2025-023759 filed on February 17, 2025. The entire disclosure of the above application is incorporated herein by reference.

### TECHNICAL FIELD

The present disclosure relates to a drip-proof sheet and an electronic control unit.

### BACKGROUND

Conventionally, a vehicle electronic control unit includes a drip shield that reduces water ingress to a connector.

### SUMMARY

According to at least one embodiment of the present disclosure, a drip-proof sheet is attached to an electronic control device that includes a circuit board and a housing. The circuit board includes a wiring board on which a connector is mounted. The housing accommodates the circuit board with the connector exposed to an outside. The drip-proof sheet includes a fixation section, a drip-proof section, and a positioning section. The fixation section is secured to the electronic control device. The drip-proof section protrudes beyond a connector wall portion of the housing to reduce water ingress to the connector. The connector wall portion is a wall from which the connector is exposed to the outside. The positioning section is attached to the electronic control device by engagement that causes the fixation section and the drip-proof section to be positioned such that the fixation section is secured to the electronic control device and the drip-proof section protrudes beyond the connector wall portion.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a perspective view of an electronic control unit according to a first embodiment.

FIG. 2 is a planar view of the electronic control unit according to the first embodiment.

FIG. 3 is a transparent view of the electronic control unit according to the first embodiment.

FIG. 4 is a transparent view of an electronic control device and a drip-proof sheet according to the first embodiment.

FIG. 5 is a transparent view of an electronic control unit according to a first modification.

FIG. 6 is a transparent view of an electronic control unit according to a second modification.

FIG. 7 is a transparent view of an electronic control unit according to a third modification.

FIG. 8 is a transparent view of an electronic control unit according to a second embodiment.

FIG. 9 is a transparent view of an electronic control unit according to a third embodiment.

FIG. 10 is a planar view of the electronic control unit according to the third embodiment.

FIG. 11 is a planar view of an electronic control unit according to a fourth embodiment.

FIG. 12 is a transparent view of the electronic control unit according to the fourth embodiment.

### DETAILED DESCRIPTION

As an example of a technique for reducing water ingress to a connector, it is conceivable to attach a drip-proof sheet to a housing of the connector using a double-sided tape. Such a drip-proof sheet may need to be applied with care to avoid misalignment, so that water ingress to the connector can be effectively reduced. In addition, an electronic control unit with a drip-proof sheet attached to an electronic control device may not be capable of reducing water ingress, depending on the misalignment of the drip-proof sheet.

According to the present disclosure, a drip-proof sheet is capable of being easily positioned.

According to the present disclosure, an electronic control unit is capable of reducing water ingress.

A drip-proof sheet of the present disclosure is attached to an electronic device that includes a circuit board and a housing. The circuit board includes a wiring board on which a connector is mounted. The housing accommodates the circuit board with the connector exposed to an outside. The drip-proof sheet includes a fixation section, a drip-proof section, and a positioning section. The fixation section is secured to the electronic control device. The drip-proof section protrudes beyond a connector wall portion of the housing to reduce water ingress to the connector. The connector wall portion is a wall from which the connector is exposed to the outside. The positioning section is attached to the electronic control device by engagement that causes the fixation section and the drip-proof section to be positioned such that the fixation section is secured to the electronic control device and the drip-proof section protrudes beyond the connector wall portion.

As describe above, the drip-proof sheet includes the positioning section attached to the electronic control device by the engagement. Thus, when the drip-proof sheet is attached to the electronic control device, the fixation section and the drip-proof section are easily positioned such that the fixation section is secured to the electronic control device and the drip-proof section protrudes beyond the connector wall portion. As a result, the drip-proof sheet can be easily positioned on the electronic control device to reduce water ingress to the connector.

An electronic control unit of the present disclosure includes an electronic control device and a drip-proof sheet. The electronic control device includes a circuit board and a housing. The circuit board includes a wiring board on which a connector is mounted. The housing accommodates the circuit board with the connector exposed to an outside. The drip-proof sheet is attached to the electronic device. The housing includes a connector wall portion that is a wall from which the connector is exposed to the outside. The drip-proof sheet includes a fixation section, a drip-proof section, and a positioning section. The fixation section is secured to the electronic control device. The drip-proof section protrudes beyond the connector wall portion to reduce water ingress to the connector. The positioning section is attached to the electronic control device by engagement that causes the fixation section and the drip-proof section to be positioned such that the fixation section is secured to the electronic control device and the drip-proof section protrudes beyond the connector wall portion.

The electronic control unit of the present disclosure includes the drip-proof sheet configured to be easily positioned on the electronic control device to reduce water ingress to the connector. As a result, the electronic control unit can reduce water ingress to the connector.

Hereinafter, multiple embodiments for carrying out the present disclosure will be described with reference to the drawings. In each embodiment, portions corresponding to those described in the preceding embodiment are denoted by the same reference numerals, and redundant descriptions will be omitted in some cases. In each embodiment, in a case where only a part of the configuration is described, another preceding embodiment can be referenced to and applied to the other parts of the configuration. Hereinafter, three directions perpendicular to each other are denoted as an X direction, a Y direction, and a Z direction.

### First Embodiment

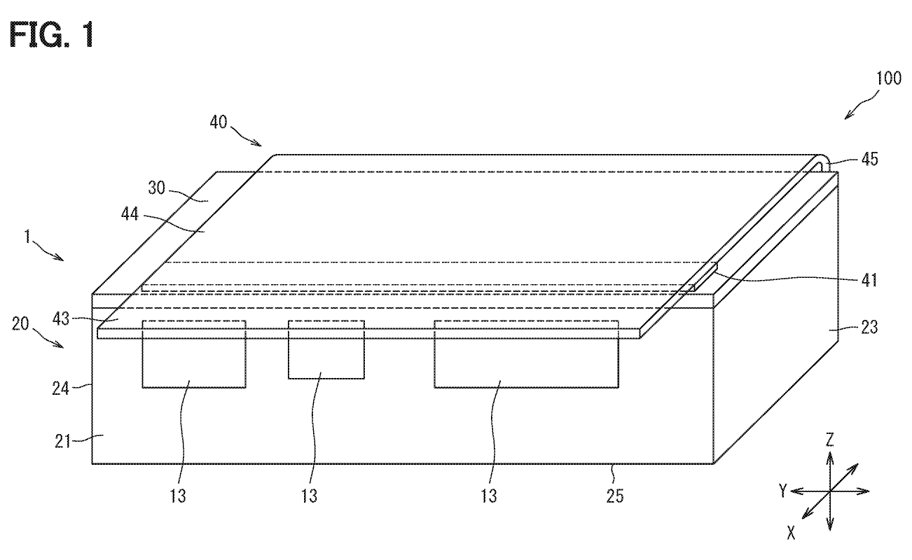

A drip-proof sheet 40 and an electronic control unit 100 according to a first embodiment will be described with reference to FIGS. 1 to 4. As shown in FIG. 1, the electronic control unit 100 includes an electronic control device 1 and the drip-proof sheet 40 attached to the electronic control device 1. The electronic control unit 100 is configured, for example, to be mountable on a mobile object. The mobile object is, for example, a vehicle such as an electric vehicle, hybrid vehicle, and fuel cell vehicle, a flying object such as an electric vertical take-off and landing aircraft and drone, a ship, construction machinery, and agricultural machinery. In the present embodiment, the electronic control unit 100 mounted on a vehicle is employed, as an example.

A state where the electronic control unit 100 is mounted on the vehicle may be simply referred to as a vehicle-mounted state. In addition, a state where the drip-proof sheet 40 is attached to the electronic control device 1 may be simply referred to as an attached state.

### Electronic Control Device

As shown in FIGS. 1, 2, and 3, the electronic control device 1 includes a circuit board 10 and a housing 20, 30, which forms an accommodation space for housing the circuit board 10. The circuit board 10 includes two wiring boards 11 and 14, and electronic components 12, 13, 15, 16 and 17 mounted on the wiring boards 11 and 14. An outside of the housing 20, 30 may be referred to as an external space.

The wiring boards 11 and 14 each include an electrically-insulating base material and conductive wiring provided on the base material. The wiring boards 11 and 14 are so-called printed circuit boards. The wiring boards 11 and 14 are stacked in the Z direction.

The wiring board 11 is provided with a circuit element 12 and an external connector 13 mounted on the wiring board 11 as the electronic components. The wiring board 14 is provided with a circuit element 15 and a debug connector 16 mounted on the wiring board 14 as the electronic components. In addition, the wiring boards 11 and 14 are provided with a board-to-board connector 17 mounted on the wiring boards 11 and 14 as an electronic component. The electronic components 12, 13, 15, 16 and 17 are electrically connected to the wiring.

The wiring board 11 may include multiple circuit elements 12 mounted thereon. Similarly, the wiring board 14 may include multiple circuit elements 15 mounted thereon.

The external connector 13 includes a terminal 13t and a connector case that encloses the terminal 13t. A portion of the terminal 13t is disposed within the accommodation space and is connected to the wiring. In addition, the terminal 13t is exposed outside the accommodation space.

The external connector 13 is for electrically connecting the electronic control device 1 to an in-vehicle device different from the electronic control device 1. The external connector 13 is connected to a mating connector 200. The external connector 13 is connected to the mating connector 200 in the vehicle-mounted state. The mating connector 200 will be described in modifications described below. The in-vehicle device may be a device to be controlled, a sensor, another electronic control device.

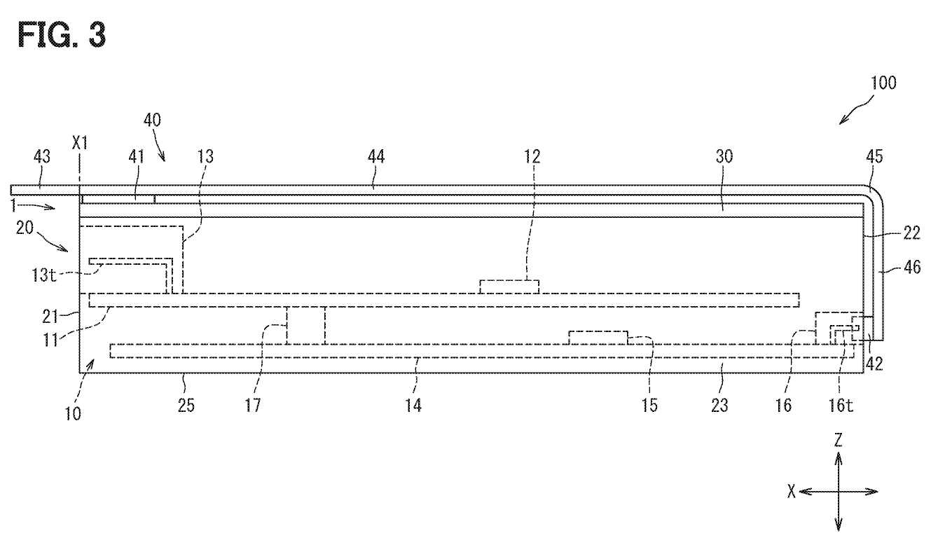

A reference numeral X1 in FIG. 3 indicates an end position of the external connector 13 in the X direction. Furthermore, the connector end X1 is an end position of the external space. The connector end X1 coincides with a side wall portion 21 in position in the X direction. However, the external connector 13 may protrude beyond the side wall portion 21. In this case, positions of the connector end X1 and the side wall portion 21 in the X direction are different from each other.

In the present embodiment, the electronic control device 1 including three external connectors 13 is employed, as an example. The three external connectors 13 are aligned in the Y direction. However, the electronic control device 1 needs to include at least one external connector 13. The external connector 13 corresponds to a connector.

The debug connector 16 includes a terminal 16t and a connector case that encloses the terminal 16t. A portion of the terminal 16t is disposed within the accommodation space and is connected to the wiring. In addition, the terminal 16t is exposed outside the accommodation space.

The debug connector 16 is connected to the mating connector 200 during development of the electronic control device 1 or when analyzing a malfunction of the electronic control device 1. The debug connector 16 is not electrically connected to the in-vehicle device. In other words, the debug connector 16 is not connected to the mating connector 200 in the vehicle-mounted state. The debug connector 16 in the vehicle-mounted state can be referred to as an unused state. Furthermore, the debug connector 16 is a connector that remains unconnected to the mating connector 200 in the unused state during normal operation of the electronic control device 1. The normal operation of the electronic control device 1 is an operation in the vehicle-mounted state.

Thus, the drip-proof sheet 40 (positioning section 42), which will be described later, can be connected to the debug connector 16 even in the vehicle-mounted state. The debug connector 16 corresponds to a specific connector. The mating connector 200 connected to the debug connector 16 is connected to devices such as inspection device or analysis device.

The specific connector to which the positioning section 42 is connected is not limited to the debug connector 16. A connector to which the mating connector 200 is not connected in the vehicle-mounted state can be adopted as the specific connector. The specific connector may be a connector that is not used depending on vehicle variations. The board-to-board connector 17 is for electrically connecting the wiring boards 11 and 14 to each other.

In the present embodiment, the circuit board 10 including the two wiring boards 11 and 14 is adopted as an example. As described above, the wiring board 11 includes the circuit elements 12 and the external connectors 13 mounted thereon. Similarly, the wiring board 14 has the circuit element 15 and the debug connector 16 mounted thereon. Thus, the electronic control device 1 can also be considered to include two circuit boards. However, the present disclosure can also employ a circuit board 10 including only a single wiring board.

The housing 20, 30 includes a base 20 and a cover 30. The base 20 includes side wall portions 21 to 24 disposed in a hollow shape, and a bottom wall portion 25 connected to one end of the side wall portions 21 to 24. The base 20 has a recessed shape defined by the side wall portions 21 to 24 and the bottom wall portion 25.

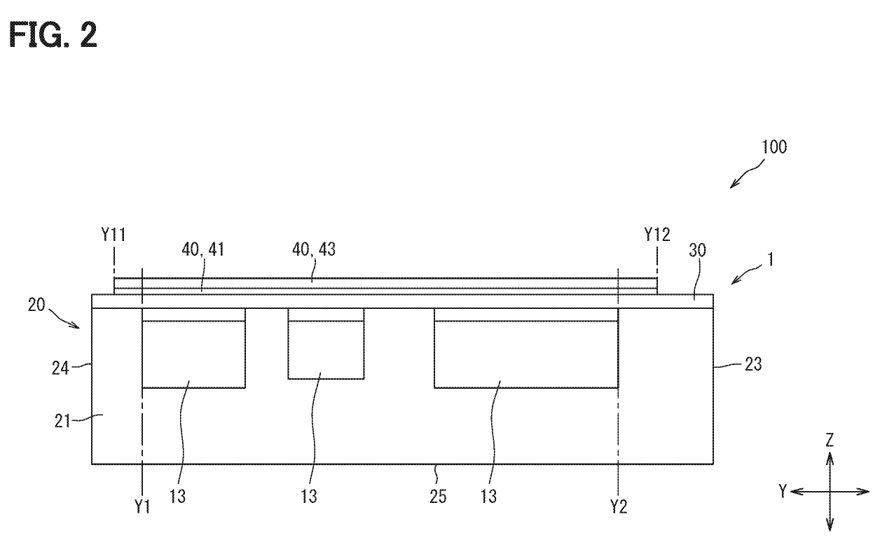

As shown in FIG. 2, the side wall portion 21 has a recessed portion recessed in the Z direction. In other words, the side wall portion 21 has the portion that is recessed in the Z direction away from the cover 30 which will be described later. The external connector 13 is disposed in the recessed portion. The recessed portion can also be referred to as a connector arrangement portion. The connector arrangement portion may be a through-hole that passes through the side wall portion 21 in the X direction. The side wall portion 21 corresponds to a connector wall portion.

A side wall portion 22 faces the side wall portion 21 in the X direction. The debug connector 16 is disposed on the side wall portion 22. For example, the side wall portion 22 includes a through-hole for disposing the debug connector 16. The side wall portion 22 corresponds to a facing wall portion. A direction from the side wall portion 22 toward the side wall portion 21 is also referred to as a positive X direction. A side wall portion 23 faces a side wall portion 24 in the Y direction.

As shown in FIG. 3, the cover 30 is disposed to face the bottom wall portion 25. The cover 30 extends in a direction crossing the side wall portions 21 to 24. The cover 30 is disposed to close an opening of the base 20. The base 20 and the cover 30 are assembled together to form the accommodation space for the circuit board 10. The cover 30 corresponds to an upper wall portion.

As shown in FIGS. 1 and 2, the circuit board 10 is accommodated in the housing 20, 30 with the external connector 13 exposed. In other words, a portion of the external connector 13 is exposed outside the accommodation space. As a result, the external connector 13 is in a state where the mating connector 200 can be connected. The external connector 13 is exposed from the side wall portion 21. Thus, the housing 20, 30 has the side wall portion 21 from which the external connector 13 is exposed.

As described above, the external connector 13 is exposed to an environment where liquids such as water droplets may adhere thereto. In addition, the electronic control device 1 has a possibility that liquid may adhere to conductive portions of the circuit board 10 via the external connector 13. The conductive portions include the terminal 13t, the wiring on the wiring boards 11 and 14, and terminals of the circuit elements 12 and 15. When liquid adheres to the conductive portions, the electronic control device 1 may have an electrical malfunction such as an electric leakage.

Thus, the electronic control unit 100 includes the drip-proof sheet 40 to reduce water ingress to the external connector 13. In other words, the electronic control unit 100 includes the drip-proof sheet 40 to reduce the adhesion of water droplets to the external connector 13. The drip-proof sheet 40 will be described below.

### Drip-Proof Sheet

As shown in FIGS. 1, 2, 3, and 4, the drip-proof sheet 40 is attached to the electronic control device 1. The drip-proof sheet 40 is attached to the housing 20, 30. For example, the drip-proof sheet 40 is attached to a portion of the base 20 and a portion of the cover 30.

For example, the drip-proof sheet 40 may employ a resin film such as polyethylene or polypropylene. The drip-proof sheet 40 is configured to be bendable. The drip-proof sheet 40 may have a longitudinal elastic modulus such that a portion (drip-proof section 43) protruding from the housing 20, 30 is not bent by its own weight. However, the drip-proof sheet 40 may have a longitudinal elastic modulus such that the drip-proof section 43 is bent by its own weight. The drip-proof sheet 40 may also be referred to as a drip-proof film or drip-proof member.

The drip-proof sheet 40, for example, has a rectangular shape. The drip-proof sheet 40 includes a fixation section 41, a positioning section 42, a drip-proof section 43, a facing section 44, a bent section 45, and an extending section 46. In the present embodiment, the drip-proof sheet 40 is adopted as an example, in which the drip-proof section 43, facing section 44, bent section 45, and extending section 46 are integrated and provided with the fixation section 41 and the positioning section 42. In other words, the drip-proof section 43, facing section 44, bent section 45, and extending section 46 form a single sheet member. However, the drip-proof sheet 40 may be configured such that the fixation section 41, positioning section 42, drip-proof section 43, facing section 44, bent section 45, and extending section 46 are formed as a single integral sheet.

In the drip-proof sheet 40, the drip-proof section 43, the facing section 44, the bent section 45, and the extending section 46 are arranged in this order. A length of the drip-proof sheet 40 in a direction from the drip-proof section 43 toward the extending section 46 is defined as a sheet length. Specifically, the sheet length is a distance from an end face of the extending section 46 to an end face of the drip-proof section 43. As shown in FIG. 3, the end face of the extending section 46 is, for example, a surface that lies along a XY plane in an attached state where the drip-proof sheet 40 is attached to the housing 20, 30. On the other hand, the end face of the drip-proof section 43 is, for example, a surface that lies along a YZ plane in the attached state. A direction along the sheet length may also be referred to as a longitudinal direction.

The XY plane is a virtual plane defined by an X-axis, which extends in the X direction, and a Y-axis, which extends in the Y direction. The YZ plane is a virtual plane defined by the Y-axis and a Z-axis which extends in the Z direction.

The drip-proof sheet 40 has a sheet width that is a length in the Y direction. A direction along the sheet width may also be referred to as a lateral direction. The drip-proof sheet 40 has a sheet thickness that is a length in the Z direction.

The fixation section 41 is a portion that secures the drip-proof sheet 40 to the cover 30. The fixation section 41 can employ a double-sided tape or adhesive. The fixation section 41 is provided between the facing section 44, which will be described later, and the cover 30. The fixation section 41 is adhered to both the facing section 44 and the cover 30. The fixation section 41 corresponds to an adhesive member. The fixation section 41 may be integrated with the facing section 44. In other words, the fixation section 41 may be a portion of the facing section 44 and may be a part having an adhesive function.

The positioning section 42 is attached to the extending section 46. The positioning section 42 is attached to the debug connector 16 by engagement. The positioning section 42 positions the fixation section 41 and the drip-proof section 43 such that the fixation section 41 is fixed to the electronic control device 1 and the drip-proof section 43 protrudes from the side wall portion 21.

The positioning section 42 is made of rubber material. The positioning section 42 corresponds to a rubber plug and a sealing member. The positioning section 42 can also be referred to as a rubber bush. The positioning section 42 can also be referred to as an elastically-deformable cover member.

As shown in FIG. 3, the positioning section 42 is attached to the debug connector 16, for example, by being inserted into the debug connector 16. In other words, the positioning section 42 is attached to a location different from the cover 30 in the electronic control device 1. In addition, the positioning section 42 can also be considered to be attached to the side wall portion 22. The positioning section 42 seals the debug connector 16 while being attached to the debug connector 16.

The positioning section 42 can be said to be attached to the debug connector 16 by engagement. The positioning section 42 can be said to be attached to the debug connector 16 by fitting. The positioning section 42 can be said to be attached to the debug connector 16 by latching. In other words, the positioning section 42 is attached to the electronic control device 1 by a method other than adhesion.

However, the positioning section 42 is not limited to this. The positioning section 42 may be provided by molding together with the drip-proof section 43, the facing section 44, the bent section 45, and the extending section 46.

As shown in FIGS. 1 and 3, the drip-proof section 43 is disposed to protrude from the side wall portion 21 in the X direction. The drip-proof section 43 can be said to be disposed to protrude in the positive X direction beyond the side wall portion 21. In addition, the drip-proof section 43 extends in the positive X direction with reference to the connector end X1. The drip-proof section 43 is a part for reducing water ingress into the external connector 13. Thus, in the vehicle-mounted state, the drip-proof section 43 is disposed above the external connector 13 in the direction of gravity. The drip-proof section 43 can also be referred to as an overhang portion.

A length of the drip-proof section 43 is set to reduce water ingress to the external connector 13. Furthermore, the length of the drip-proof section 43 is set, for example, through experiments or simulations. The length of the drip-proof section 43 can also be referred to as a protrusion amount of the drip-proof sheet 40 from the side wall portion 21. The length of the drip-proof section 43 is its length in the longitudinal direction.

The facing section 44 is a part that faces the cover 30 in the Z direction. The facing section 44 is disposed to be continuous with the drip-proof section 43 and the bent section 45. The bent section 45 is a part that is bent with respect to the facing section 44. The bent section 45 is disposed to be continuous with the facing section 44 and the extending section 46. The extending section 46 is a part that extends from the bent section 45 to the debug connector 16. The extending section 46 is a part that faces the side wall portion 22 in the X direction. The bent section 45 and the extending section 46 are disposed above the debug connector 16 in the direction of gravity in the vehicle-mounted state.

As shown in FIG. 3, the sheet length is set such that the drip-proof section 43 protrudes beyond the side wall portion 21 when the positioning section 42 is attached to the debug connector 16. In addition, a total length of the facing section 44, the bent section 45, and the extending section 46 is set to reach an end portion of the cover 30 positioned at the side wall portion 21 from the debug connector 16 along the housing 20, 30. In other words, the facing section 44, the bent section 45, and the extending section 46 have a length such that the fixation section 41 is positioned at the end portion of the cover 30 facing the side wall portion 21 while the positioning section 42 is attached to the debug connector 16.

The end portion of the cover 30 facing the side wall portion 21 is a portion of a surface along the XY plane. The end portion of the cover 30 facing the side wall portion 21 is a fixation region where the fixation section 41 is secured.

As shown in FIG. 2, the sheet width corresponds to a distance between a first sheet end portion Y11 and a second sheet end portion Y12. The first sheet end portion Y11 is at one side of the drip-proof sheet 40, and the second sheet end portion Y12 is at the other side of the drip-proof sheet 40. A connector width of the external connector 13 is a length along the Y direction. The connector width corresponds to a distance between a first connector end portion Y1 and a second connector end portion Y2. The first connector end portion Y1 is at one side of all the external connectors 13, and the second connector end portion Y2 is at the other side of all the external connectors 13.

The sheet width may be greater than the connector width. As a result, the drip-proof sheet 40 can more effectively prevent water droplets from adhering to the external connector 13. The sheet width may be greater than a distance between the side wall portion 23 and the side wall portion 24.

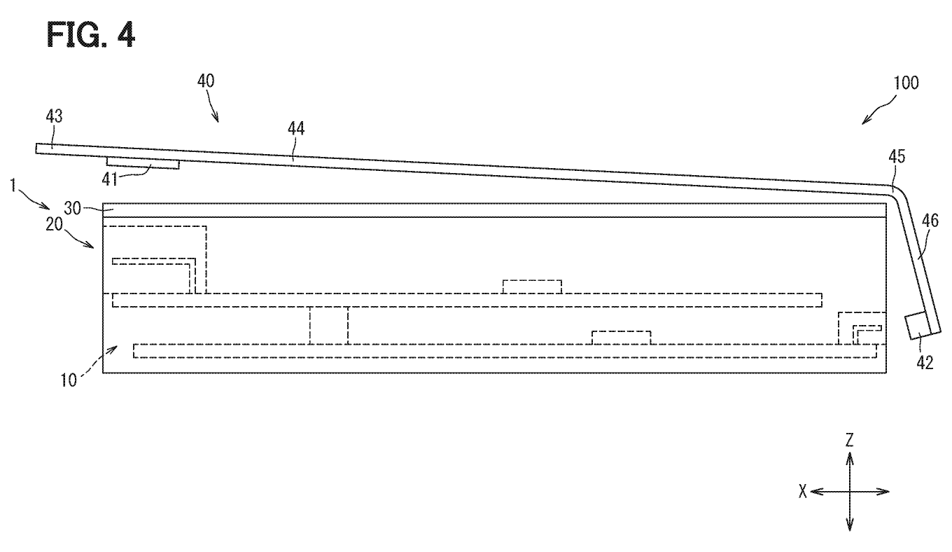

As shown in FIG. 4, the drip-proof sheet 40 is disposed separately from the electronic control device 1 and is attached to the electronic control device 1. For positioning of the drip-proof section 43, the positioning section 42 is attached to the debug connector 16 at first. Then, the fixation section 41 is attached to the cover 30. At this time, since the positioning section 42 of the drip-proof sheet 40 is attached to the debug connector 16, the fixation section 41 can be easily fixed to an appropriate location. In this state, the drip-proof sheet 40 is disposed such that the drip-proof section 43 protrudes beyond the side wall portion 21.

### Effects

As described above, the drip-proof sheet 40 includes the positioning section 42 attached to the electronic control device 1 by engagement. Thus, the drip-proof sheet 40 can be easily positioned so that the fixation section 41 is secured to the electronic control device 1 while the drip-proof section 43 protrudes from the side wall portion 21 when attaching the drip-proof sheet 40 to the electronic control device 1. As a result, the drip-proof sheet 40 can be easily positioned relative to the electronic control device 1 so that the drip-proof sheet 40 can reduce water ingress into the external connector 13.

Since the drip-proof sheet 40 allows the fixation section 41 to be secured to the electronic control device 1 while the positioning section 42 is attached to the electronic control device 1 by engagement, workability can be improved. In other words, the drip-proof sheet 40 can be attached more easily to the electronic control device 1 than a configuration in which the drip-proof sheet 40 is attached to the electronic control device 1 using only double-sided tape. Furthermore, it is also possible to prevent the drip-proof sheet 40 from peeling up when attaching the drip-proof sheet 40 to the electronic control device 1.

Since the drip-proof sheet 40 seals the debug connector 16 by the positioning section 42, water ingress to the debug connector 16 can also be reduced. In addition, the drip-proof sheet 40 can block a water ingress-path from the debug connector 16 to the accommodation space. Furthermore, the drip-proof sheet 40 can also reduce water ingress to the debug connector 16 by the bent section 45 and the extending section 46.

In addition, the electronic control unit 100 includes the drip-proof sheet 40. Therefore, the electronic control unit 100 can reduce water ingress to the external connector 13.

### First Modification

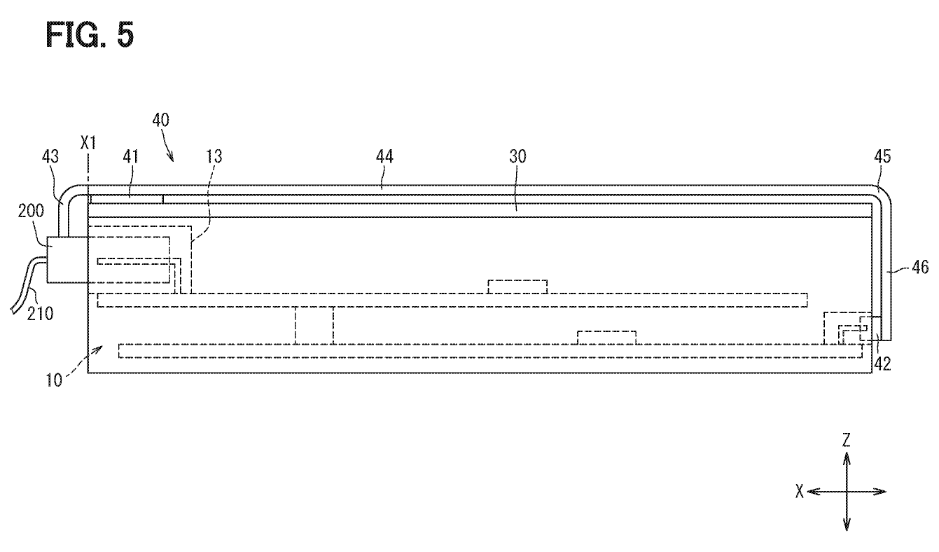

As shown in FIG. 5, the external connector 13 is connected to a mating connector 200. The terminal 13t is electrically connected to a wire 210 by the mating connector 200 connected to the external connector 13. Here, the mating connector 200 is electrically connected to the in-vehicle device via the wire 210.

In a first modification, the drip-proof sheet 40 includes a drip-proof section 43 extending to a position to be in contact with the mating connector 200. The drip-proof sheet 40 has the longitudinal elastic modulus such that the drip-proof section 43 is bent in the attached state. In other words, the drip-proof sheet 40 can be said to have a bending rigidity so that the drip-proof section 43 is bent in the attached state. Thus, the drip-proof section 43 is bent in the Z direction to reach the external connector 13 or the mating connector 200. In other words, the drip-proof section 43 can be said to hang down to reach the external connector 13 or the mating connector 200.

The drip-proof sheet 40 may have different bending rigidities in different portions. For example, the drip-proof sheet 40 may have the facing section 44 and the extending section 46 that have greater bending rigidity than that of the drip-proof section 43 and the bent section 45.

The drip-proof sheet 40 can achieve the same effects as that of the above embodiment. Furthermore, the drip-proof sheet 40 can reduce water ingress to a connection portion between the external connector 13 and the mating connector 200. Thus, the drip-proof sheet 40 can reduce water ingress to the mating connector 200. The electronic control unit 100 may include the drip-proof sheet 40 of the first modification. The drip-proof section 43 according to the first modification can be applied to other embodiments and modifications.

### Second Modification

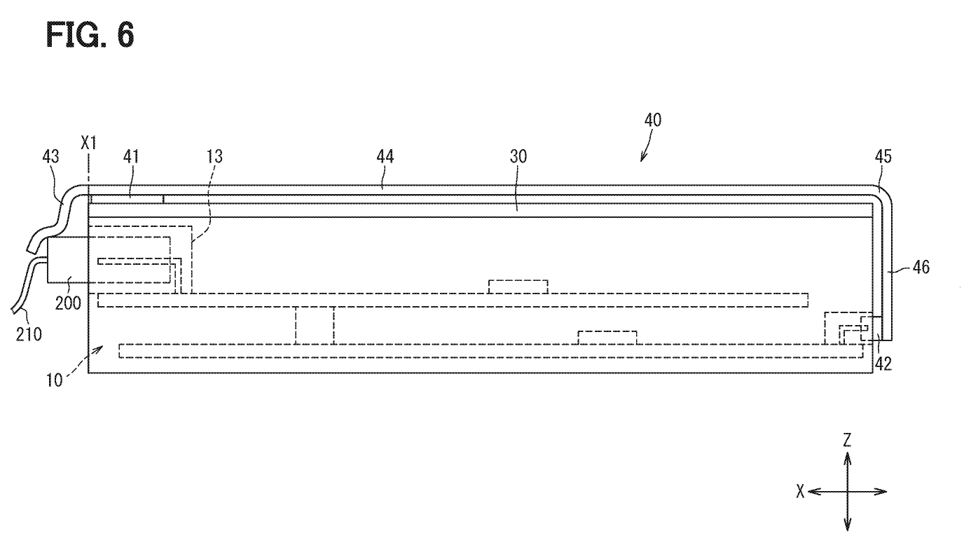

As shown in FIG. 6, in a second modification, a drip-proof section 43 of a drip-proof sheet 40 is disposed to extend to a position where the drip-proof sheet 40 is in contact with a wire 210 of the mating connector 200. The drip-proof sheet 40 can achieve the same effects as that in the first modification. Furthermore, the drip-proof sheet 40 can reduce water ingress between the mating connector 200 and the wire 210. The electronic control unit 100 may include the drip-proof sheet 40 of the second modification. The drip-proof section 43 according to the second modification can be applied to other embodiments or modifications.

### Third Modification

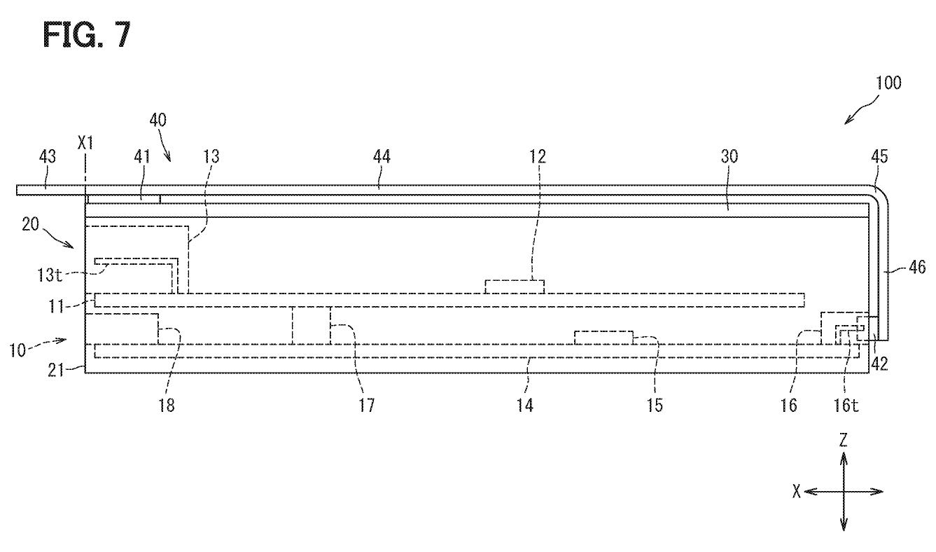

As shown in FIG. 7, the wiring board 14 may include an external connector 18 mounted thereon. In other words, the electronic control device 1 includes the external connector 18 in addition to a configuration of the first embodiment. The external connector 18 is exposed to the outside from the side wall portion 21 similarly to the external connector 13. The external connector 18 is different from the external connector 13 in position in the Z direction.

The drip-proof sheet 40 is disposed to protrude beyond the side wall portion 21 as described above. Thus, the drip-proof sheet 40 can reduce water ingress to the external connector 18. The electronic control device 1 according to the third modification can be applied to other embodiments and modifications.

### Second Embodiment

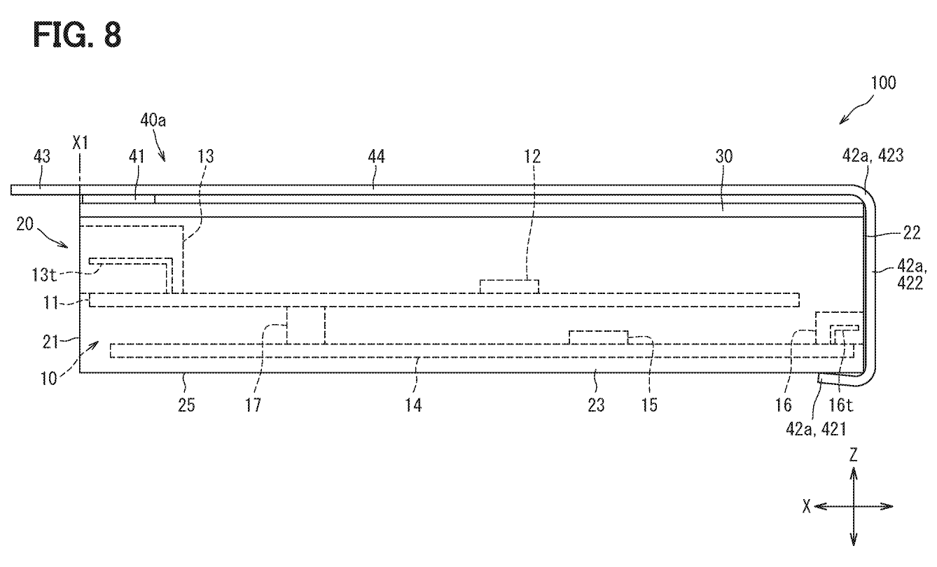

An electronic control unit 100 according to a second embodiment will be described with reference to FIG. 8. The electronic control unit 100 includes a drip-proof sheet 40a instead of the drip-proof sheet 40. The wiring board 14 may not have the debug connector 16 mounted thereon.

As shown in FIG. 8, the drip-proof sheet 40a is different from the drip-proof sheet 40 in configuration of a positioning section 42a. The positioning section 42a includes a first engaging section 421, an intermediate section 422, and a second engaging section 423. The first engaging section 421 is a section that engages with a corner between the side wall portion 22 and the bottom wall portion 25. The first engaging section 421 is disposed to be continuous with the intermediate section 422.

The intermediate section 422 is a section that faces the side wall portion 22. In addition to the first engaging section 421, the intermediate section 422 is disposed to be continuous with the second engaging section 423. The second engaging section 423 is a section that engages with a corner between the side wall portion 22 and the cover 30. The drip-proof sheet 40a is disposed so that the positioning section 42a engages with the housing 20, 30.

As described above, the positioning section 42a can be referred to as clamping sections 421, 422, and 423 that clamp the cover 30 and the bottom wall portion 25 while facing the side wall portion 22. Thus, the positioning section 42a is configured to be elastically deformable. In addition, the positioning portion 42a deforms to conform to the shape of the housing 20, 30. Then, the positioning section 42a engages with the housing 20, 30 by a restoring force that returns to an original shape of the positioning section 42a. The positioning section 42a may have a shape that conforms to outer contours of the base 20 and the cover 30.

The drip-proof sheet 40a can achieve the same effects as the drip-proof sheet 40. Furthermore, the drip-proof sheet 40a can be attached even to the electronic control device 1 that does not include the debug connector 16. The electronic control unit 100 can achieve the same effects as that of the above embodiment.

### Third Embodiment

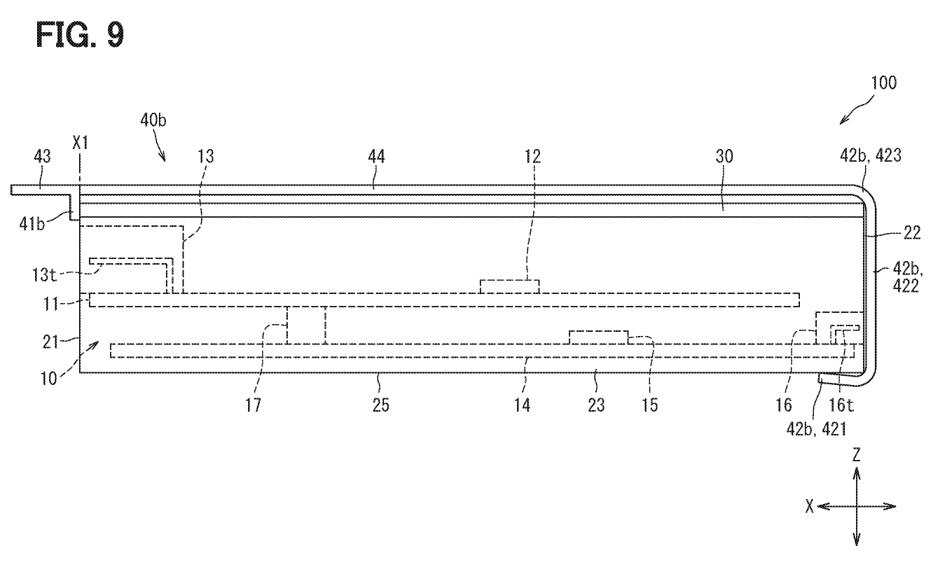

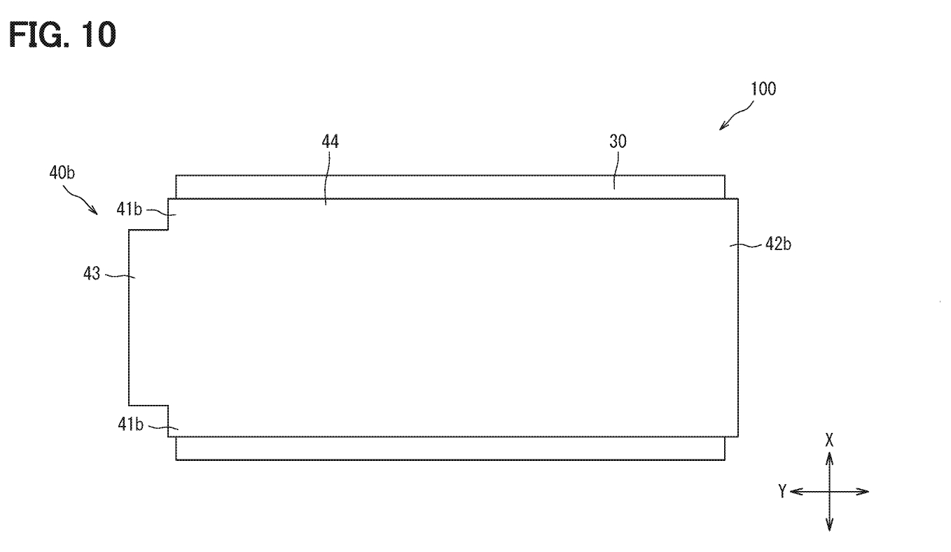

An electronic control unit 100 according to a third embodiment will be described with reference to FIGS. 9 and 10. The electronic control unit 100 includes a drip-proof sheet 40b instead of the drip-proof sheet 40. The wiring board 14 may not have the debug connector 16 mounted thereon.

As shown in FIGS. 9 and 10, the drip-proof sheet 40b is different from the drip-proof sheet 40 in configuration of fixation sections 41b. A positioning section 42b has the same configuration as the positioning section 42a. In the third embodiment, the positioning section 42 may also be used instead of the positioning section 42b.

Each of the fixation sections 41b is a section that is bent with respect to the drip-proof section 43. Each fixation section 41b is a bent section that is in contact with the side wall portion 21. In addition, each fixation section 41b is also bent with respect to the facing section 44. The drip-proof sheet 40b includes the fixation sections 41b at a position in the Y direction to clamp the external connector 13. In other words, the drip-proof sheet 40b includes two fixation sections 41b. The drip-proof sheet 40b includes at least one fixation section 41b.

The fixation sections 41b are secured to the electronic control device 1 with the positioning section 42b engaged with the housing 20, 30. The fixation sections 41b are secured to the electronic control device 1 by clamping the housing 20, 30 together with the positioning section 42b. The fixation sections 41b, the facing section 44, and the positioning section 42b may have bending rigidity such that they are not bent under their own weight.

The drip-proof sheet 40b can achieve the same effects as the drip-proof sheet 40. Furthermore, the drip-proof sheet 40b can be attached to the electronic control device 1 without using a double-sided tape or adhesive. The electronic control unit 100 can achieve the same effects as those of the above embodiment.

### Fourth Embodiment

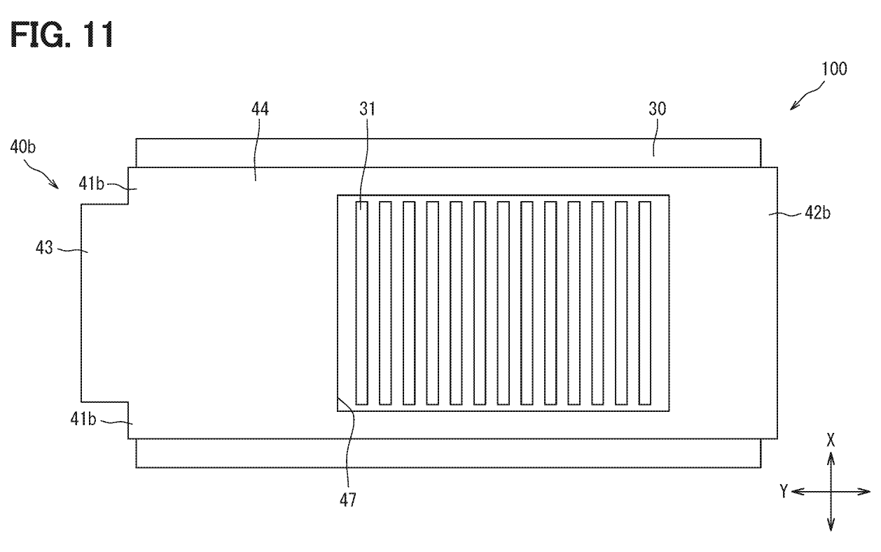

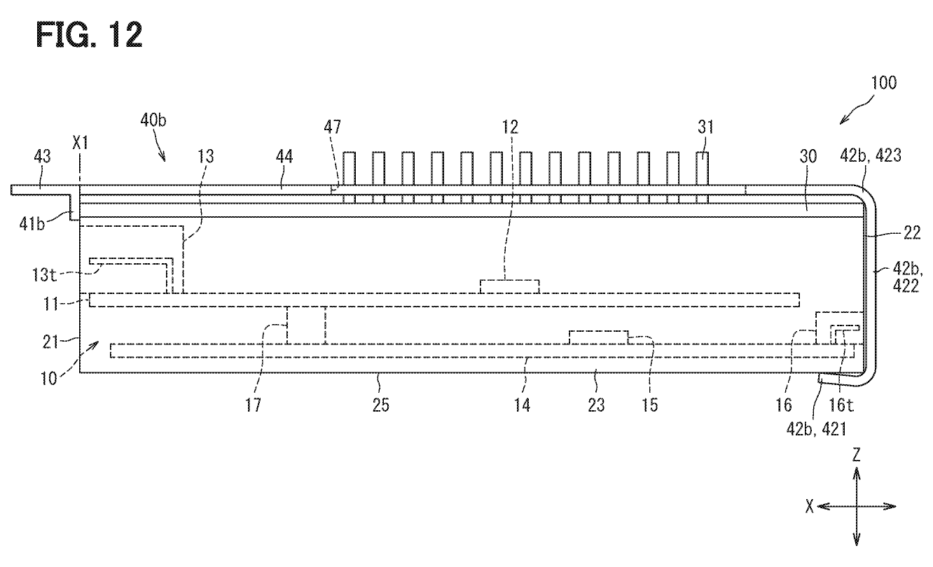

An electronic control unit 100 according to a fourth embodiment will be described with reference to FIGS. 11 and 12. A drip-proof sheet 40b is different from that of the third embodiment in presence of an opening 47.

As shown in FIGS. 11 and 12, the cover 30 includes heat sink fins 31. The drip-proof sheet 40b is attached to the housing 20, 30 with the heat sink fins 31. The drip-proof sheet 40b includes the opening 47 in which the heat sink fins 31 are disposed.

This embodiment can achieve the same effects as the third embodiment. Furthermore, the drip-proof sheet 40b can be easily positioned relative to the electronic control device 1 while ensuring heat dissipating performance of the electronic control device 1. The opening 47 can be applied to the drip-proof sheet 40 and the drip-proof sheet 40a.

The embodiments of the present disclosure have been described above. The present disclosure is not limited to the above embodiments or structures. The present disclosure covers various modifications and equivalents. In addition, while various combinations and modes are described in the present disclosure, other combinations and modes including only one element, more elements, or less elements therein are also within the scope and spirit of the present disclosure.

What is claimed is:

1. A drip-proof sheet attached to an electronic control device that includes a circuit board and a housing, the circuit board including a wiring board on which a connector is mounted, the housing accommodating the circuit board with the connector exposed to an outside, the drip-proof sheet comprising:
a fixation section secured to the electronic control device;
a drip-proof section protruding beyond a connector wall portion of the housing to reduce water ingress to the connector, the connector wall portion being a wall from which the connector is exposed to the outside; and
a positioning section attached to the electronic control device by engagement that causes the fixation section and the drip-proof section to be positioned such that the fixation section is secured to the electronic control device and the drip-proof section protrudes beyond the connector wall portion.

2. The drip-proof sheet according to claim 1, wherein
the circuit board includes a specific connector that is unused and unconnected to a mating connector during normal operation of the electronic control device, and
the positioning section includes a sealing member that is attached to the specific connector and seals the specific connector.

3. The drip-proof sheet according to claim 2, wherein
the sealing member includes a rubber plug.

4. The drip-proof sheet according to claim 1, wherein
the housing includes:
a facing wall portion facing the connector wall portion;
a bottom wall portion continuous with the connector wall portion and the facing wall portion; and
an upper wall portion facing the bottom wall portion, and
the positioning section includes a clamping section configured to face the facing wall portion and clamp the upper wall portion and the bottom wall portion.

5. The drip-proof sheet according to claim 1, wherein
the fixation section includes an adhesive member.

6. The drip-proof sheet according to claim 1, wherein
the fixation section includes a bent section bent relative to the drip-proof section and in contact with the connector wall portion.

7. The drip-proof sheet according to claim 1, wherein
the housing includes heat sink fins, and
the drip-proof sheet further comprises an opening where the heat sink fins are disposed.

8. An electronic control unit, comprising:
an electronic control device that includes a circuit board and a housing, the circuit board including a wiring board on which a connector is mounted, the housing accommodating the circuit board with the connector exposed to an outside; and
a drip-proof sheet attached to the electronic control device, wherein
the housing includes a connector wall portion that is a wall from which the connector is exposed to the outside, and
the drip-proof sheet includes:
a fixation section secured to the electronic control device;
a drip-proof section protruding beyond the connector wall portion to reduce water ingress to the connector; and
a positioning section attached to the electronic control device by engagement that causes the fixation section and the drip-proof section to be positioned such that the fixation section is secured to the electronic control device and the drip-proof section protrudes beyond the connector wall portion.

9. The drip-proof sheet according to claim 1, wherein
the housing includes a facing wall portion facing the connector wall portion, and
the positioning section extends in a direction from the facing wall portion to the connector wall portion.
